(19) United States
(12) Patent Application Publication
(10) Pub. No.: US 2006/0005877 A1
(43) Pub. Date: Jan. 12, 2006

(54) Passivated, dye-sensitized oxide semiconductor electrode, solar cell using same, and method

(75) Inventors: James Lawrence Spivack, Cobleskill, NY (US); Shellie Virginia Gasaway, Schenectady, NY (US); Oltea Puica Siclovan, Rexford, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 10/884,028

(22) Filed: Jul. 6, 2004

(51) Int. Cl. H01L 31/00

(52) U.S. Cl. 136/263; 136/252

(57) ABSTRACT

Disclosed is a dye-sensitized oxide semiconductor electrode comprising an electrically conductive substrate, an oxide semiconductor film provided on a surface of said electrically conductive substrate, and a sensitizing dye adsorbed on said film, wherein the oxide semiconductor film has been further treated with at least one silanizing agent comprising the partial structure R¹—Si—OR², wherein R¹ and R² are each independently alkyl groups, or R¹ is an alkyl group and R² is hydrogen or aryl. Also disclosed are solar cells comprising said electrode and a method for improving the efficiency of the solar cells. The solar cells exhibit improved efficiency and other beneficial properties compared to similar cells not having the passivated electrode.

### BACKGROUND OF THE INVENTION

The present invention relates to a dye-sensitized oxide semiconductor electrode having a passivated surface. The present invention is also directed to a high efficiency solar cell comprising such an electrode. In one particular embodiment the present invention relates to a high efficiency solar cell comprising a dye-sensitized electrode with a silanized surface.

One type of known solar cell comprises an electrode comprising an oxide semiconductor such as titanium oxide or zinc oxide. It is also known to adsorb a sensitizing dye capable of absorbing light in the visible or near infrared region on such an electrode for the purpose of improving light energy absorbing efficiency thereof. Often, such dye sensitized solar cells (DSSC) comprise an electrode comprising a layer of high surface area oxide semiconductor on a transparent conducting oxide film with a monolayer of dye attached to the oxide semiconductor. The absorption of light creates the excited state of the dye which injects an electron into the oxide semiconductor electrode leaving behind an oxidized dye cation. This oxidized dye is reduced by transfer of an electron from a reducing species such as an iodide ion, leading to the production of triiodide (or other oxidizing species) which picks up an electron from an appropriate counter electrode, thereby closing the circuit and generating electrical energy from light.

The solar cell must operate at high efficiency in order to produce low-cost power. A major limitation on efficiency is the loss of electrons from the oxide semiconductor and the underlying conducting oxide layer to iodine and triiodide (or other oxidizing species) in the electrolyte; this is referred to as charge recombination. One of the contributing factors to this recombination is the length of time it takes for an electron to diffuse through the oxide semiconductor to the underlying conducting oxide. During the approximately 10 milliseconds such diffusion typically takes, there is ample time for recombination events to take place.

Another important limitation on cell efficiency is the rate of ion transport (for example, triiodide) between the counter electrode and the surface absorbed dye. This problem may be especially severe under full sun illumination when using high boiling or viscous solvents in the electrolyte mixture. Such solvents are often required to ensure cell longevity, especially when fabricating cells on polymer substrates, because such substrates are prone to allow low boiling non-viscous solvents to diffuse out over time. One approach to avoiding limitations due to ion diffusion is to take advantage of charge hopping mechanisms (for example, Grotthus mechanism) which operate most efficiently at high concentrations of the active species. Thus, for example, electrolytes with high (e.g. 0.5 M) triiodide concentrations are not diffusion limited. But at high concentrations of the oxidant the electron recombination rate increases and becomes limiting. Thus, there is a continuing need for a method for reducing the rate of charge recombination at oxide semiconductor surfaces in DSSC's. In addition, there is a continuing need for methods to improve the efficiency of DSSC's.

A method for reducing the rate of charge recombination in dye-sensitized solar cells has been reported by Gregg et al. in Journal of Physical Chemistry B (2001), volume 105, pp. 1422-1429. The method requires passivation of an electrode surface with methylchlorosilane vapor. Chlorosilanes in toluene solution and silanes less reactive than chlorosilanes did not work for passivation. In addition, passivation of the electrode surface actually resulted in a decrease in efficiency in solar cells with iodine electrolyte.

### BRIEF DESCRIPTION OF THE INVENTION

The present inventors have discovered a novel dye-sensitized oxide semiconductor electrode with a passivated surface. Thus, in one embodiment the present invention is a dye-sensitized oxide semiconductor electrode comprising an electrically conductive substrate, an oxide semiconductor film provided on a surface of said electrically conductive substrate, and a sensitizing dye adsorbed on said film, wherein the oxide semiconductor film has been further treated with at least one silanizing agent comprising the partial structure R¹—Si—OR , wherein R¹ and R² are each independently alkyl groups, or R¹ is an alkyl group and R² is hydrogen or aryl. Also disclosed are solar cells comprising said electrode and a method for improving the efficiency of the solar cells. The solar cells exhibit improved efficiency and other beneficial properties compared to similar cells not having the passivated electrode. Various other features, aspects, and advantages of the present invention will become more apparent with reference to the following description and appended claims.

### DETAILED DESCRIPTION OF THE INVENTION

In the following specification and the claims which follow, reference will be made to a number of terms which shall be defined to have the following meanings. The singular forms “a”, “an” and “the” include plural referents unless the context clearly dictates otherwise. “Optional” or “optionally” means that the subsequently described event or circumstance may or may not occur, and that the description includes instances where the event occurs and instances where it does not.

A solar cell of the present invention comprises a dye-sensitized oxide semiconductor electrode, a counter electrode and an electrolyte solution (sometimes referred to as redox electrolyte) disposed between the above electrodes. The oxide semiconductor electrode may be prepared by applying a dispersion or slurry containing fine powder of an oxide semiconductor on an electrically conducting substrate to form a semiconductor layer. It is generally preferable that the oxide semiconductor powder has as small a diameter as possible. Generally the particle size of the oxide semiconductor particles is not greater than about 5,000 nanometers (nm), and preferably not greater than about 50 nm. In one embodiment a mix or bilayer system comprising oxide semiconductor particles of at least two different particle sizes may be beneficially employed. In a particular illustrative embodiment both 15-20 nm oxide semiconductor particles to provide high surface area and 200-400 nm particles to scatter light may be employed. The semiconductor particles generally have a specific surface area of at least about 5 square meters per gram (m²/g), preferably at least about 10 m²/g, and more preferably in a range of about 50-150 m²/g. Any solvent may be used for dispersing the semiconductor particles therein. Water, an organic solvent or a mixture thereof may be used. Illustrative examples of suitable organic solvents comprise alcohols such as methanol and ethanol, ketones such as acetone, methyl ethyl ketone and acetyl acetone, and hydrocarbons such as hexane and cyclohexane. Additives such as a surfactant and/or a thickening agent (e.g. a polyether such as polyethylene glycol) may be added into the dispersion. The dispersion generally has a content of the oxide semiconductor particles in the range of 0.1-70% by weight, and preferably 0.1-30% by weight.

Any conventionally used oxide semiconductor particles may be used for the oxide semiconductor electrode. Suitable oxide semiconductors are typically wide bandgap materials, and include, but are not limited to, those with a band gap of at least about 1.7 electron volts (eV) and often at least about 3 eV. Examples of oxide semiconductors include oxides of metals such as Ti, Nb, Zn, Sn, Zr, Y, La, Ta, W, Hf, Sr, In, V, Cr, and Mo; and perovskite oxides such as SrTiO₃ and CaTiO₃. Mixtures of oxide semiconductors may also be employed. In some embodiments of the present invention a coated oxide semiconductor electrode may be used. Suitable coating materials are typically metal oxides which have a conduction band energy higher than that of the conduction band of the oxide semiconductor and higher than that of the excited state oxidation potential of the sensitizing dye. Suitable coating materials comprise alumina, silica, zirconia (ZrO₂), or niobium oxide (Nb₂O₅). In a particular embodiment an alumina-coated titania electrode may be used. Suitable coated electrodes are described, for example by Palomares et al. in Journal of the American Chemical Society (2003), volume 125, pp. 475-482 and by Ichinose et al. in Chemistry of Materials (1997), volume 9, pp. 1296-1298.

After the dispersion of oxide semiconductor particles is applied onto a surface of a substrate, the coating is typically dried and calcined in air or in an inert atmosphere to form a layer of the oxide semiconductor. Any known electrically conducting substrate may be suitably used for the purpose of the present invention. Thus, the substrate may be, for example, a refractory plate such as a glass plate on which an electrically conductive layer comprising a material such as In₂O₃ or SnO₂ is laminated, or an electrically conductive metal foil or plate, or an electrically conducting ceramic, or ceramic coated with an electrical conductor, or an electrically conductive polymer. The thickness of the substrate is not specifically limited but is generally in a range of about 0.3-5 mm. The substrate may be opaque, transparent or translucent.

The sensitizing dye is applied to a surface of the electrode to adsorb the dye thereon. Within the present context the term “electrode surface” encompasses the oxide semiconductor surface and any coating that may optionally be present on the oxide semiconductor. Suitable sensitizing dyes comprise those known in the art. In suitable dyes the excited state oxidation potential is typically higher than the semiconductor conduction band energy. Some illustrative suitable dyes include, but are not limited to, those comprising coumarins, cyanines, merocyanines, polymethines, perylenes, squaraines, porphyrins, or phthalocyanines, optionally further comprising a metal. The dye may be applied as a solution or colloidal suspension in a liquid. The adsorbed dye layer is preferably a monomolecular layer. If desired, two or more kinds of sensitizing dyes may be used in combination to broaden the range of wavelengths of light which is absorbed by the dye-sensitized electrode. To adsorb a plurality of sensitizing dyes, a common solution containing all sensitizing dyes can be used. Alternatively, a plurality of solutions containing respective dyes can be used. Any suitable solvent may be used for dissolving the sensitizing dye. Illustrative examples of suitable solvents comprise methanol, ethanol, t-butanol, acetonitrile, dimethylformamide and dioxane. The concentration of the dye solution is suitably determined according to the kind of the dye. The sensitizing dye is generally dissolved in the solvent in an amount of 1-10,000 milligrams (mg), preferably 10-500 mg, per 100 milliliters (ml) of the solvent. In some embodiments examples of suitable dyes comprise metal complexes such as complexes of ruthenium or osmium. Some particular, non-limiting examples of suitable dyes comprise ruthenium complexes such as cis-bis(isothiocyanato)(2,2′-bipyridyl-4,4′-dicarboxylato)(4,4′-n-nonyl-2,2′-bipyridyl)ruthenium(II); cis-bis(isothiocyanato)bis(2,2′-bipyridyl-4,4′-dicarboxylato)-ruthenium(II), and the like, and ruthenium complexes such as those described in U.S. Pat. No. 6,639,073.

After the electrode surface is treated with dye, the electrode surface is exposed to the silanizing agent. Although the invention is not dependent upon any theory of operation, it is believed that the silanizing agent bonds to the portions of the electrode surface that the dye has failed to cover. The silanizing agent may react with hydroxy groups or other reactive heteroatom sites on the electrode surface to produce an electrically insulating film which does not conduct electrons as well as the uncoated surface. Thus, silanization effectively inhibits electron recombination and typically increases the efficiency of the DSSC.

Silanizing agents suitable for use in the present invention comprise those comprising the partial structure R¹—Si—OR², wherein R¹ and R² are each independently alkyl groups, or R¹ is an alkyl group and R² is hydrogen or aryl. Illustrative examples of suitable silanizing agents include, but are not limited to, alkylsilanes of the formula R¹ₙSi(OR²)₄₋ₙ; bis(silyl)alkanes of the formula R¹(Si(OR²)₃)₂; tris(silyl)alkanes of the formula R¹(Si(OR²)₃)₃; and tetrakis(silyl)alkanes of the formula R¹Si(OR²)₃)₄; wherein the parameter n has a value of 1-3 inclusive and in each case R¹ and R² are each independently alkyl groups, or R¹ is an alkyl group and R² is hydrogen or aryl. Suitable silanizing agents also include, but are not limited to, functionalized silylalkanes with charged groups such as those of the formula (R²O)₃Si(CH₂)ₘPO₃⁻X⁺, wherein R² is hydrogen, alkyl or aryl, the counterion X includes, but is not limited to, tetraalkylammonium, and the parameter m has a value in the range of 2-16 inclusive; or those of the formula (R²O)₃Si(CH₂)ₘNR³₃⁺Y⁻, wherein R² is hydrogen, alkyl or aryl, R³ is an alkyl group, the counterion Y includes, but is not limited to, iodide, and the parameter m has a value in the range of 2-16 inclusive; and silylated polyethylenes such as those of the formula (I)
—[CH₂CH₂]ₚ—[CH₂CH(SiR¹ₙ(OR²)₃₋ₙ)]ₓ— (I)
wherein R¹ and R² are each independently hydrogen, alkyl or aryl, the parameter n has a value of 1-3 inclusive, and the parameters p and x each independently have a value in a range of about 4-100.

The term “alkyl” as used in the various embodiments of the present invention is intended to designate linear alkyl, branched alkyl, aralkyl, cycloalkyl, bicycloalkyl, tricycloalkyl and polycycloalkyl radicals containing carbon and hydrogen atoms, and optionally containing atoms in addition to carbon and hydrogen, for example atoms selected from Groups 15, 16 and 17 of the Periodic Table. Illustrative examples of substituents on alkyl groups include, but are not limited to, ether, alkoxy, ester and halogen. In some specific embodiments alkyl groups may be either partially fluorinated or perfluorinated. In other specific embodiments alkyl groups may comprise 3,3,3-trifluoropropyl or methoxypropyl. In particular embodiments alkyl groups are saturated. The term “alkyl” also encompasses that alkyl portion of alkoxy groups. In various embodiments normal and branched alkyl radicals are those containing from 1 to about 16 carbon atoms, and include as illustrative non-limiting examples C₁-C₁₆ alkyl (optionally substituted with one or more groups selected from C₁-C₁₆ alkyl, C₃-C₁₅ cycloalkyl or aryl); and C₃-C₁₅ cycloalkyl optionally substituted with one or more groups selected from C₁-C₁₆ alkyl. Some particular illustrative examples comprise methyl, ethyl, n-propyl, isopropyl, n-butyl, sec-butyl, tertiary-butyl, pentyl, neopentyl, hexyl, heptyl, octyl, nonyl, decyl, undecyl, dodecyl, hexadecyl and octadecyl. Some illustrative non-limiting examples of cycloalkyl and bicycloalkyl radicals include cyclobutyl, cyclopentyl, cyclohexyl, methylcyclohexyl, cycloheptyl, bicycloheptyl and adamantyl. In various embodiments aralkyl radicals are those containing from 7 to about 14 carbon atoms; these include, but are not limited to, benzyl, phenylbutyl, phenylpropyl, and phenylethyl. The term “aryl” as used in the various embodiments of the present invention is intended to designate substituted or unsubstituted aryl radicals containing from 6 to 20 ring carbon atoms. Some illustrative non-limiting examples of these aryl radicals include C₆-C₂₀ aryl optionally substituted with one or more groups selected from C₁-C₃₂ alkyl, C₃-C₁₅ cycloalkyl or aryl. Some particular illustrative examples of aryl radicals comprise substituted or unsubstituted phenyl, biphenyl, tolyl, naphthyl and binaphthyl.

Some illustrative, non-limiting examples of suitable silanizing agents include, but are not limited to, n-hexyltrimethoxysilane, n-octyltrimethoxysilane, isooctyltrimethoxysilane, 2,4,4-trimethylpentyltrimethoxysilane, octadecyltrimethoxysilane, hexadecyltrimethoxysilane, dodecyltrimethoxysilane, 1,8-bis(triethoxysilyl)octane, 1,10-bis(trimethoxysilyl)decane, 1,12-bis(trimethoxysilyl)dodecane, 1,14-bis(trimethoxysilyl)tetradecane, 1,16-bis(trimethoxysilyl)hexadecane and 2-(perfluorohexylethyl)trimethoxysilane. In addition suitable silanizing agents include, but are not limited to, functionalized silanes of the types disclosed in U.S. Pat. Nos. 3,722,181 and 3,795,313. Optimum silanizing agents may be dependent upon such factors as the steric and electronic properties of the R groups, the identity of the dye used in the solar cell, the morphology of the electrode surface, the parameters of the silanizing process (such as, but not limited to, temperature, time, solvent, and concentration), and like factors which may be readily determined without undue experimentation by those skilled in the art.

Silanization of the oxide semiconductor electrode surface to form a passivated electrode may be performed by any convenient method. In one embodiment the method comprises the step of treating the electrode surface with neat silanizing agent for a suitable period of time. In a preferred embodiment the method comprises the step of treating the electrode surface with a solution or suspension of silanizing agent in a suitable solvent. Preferred solvents are those which are inert and which substantially dissolve the silanizing agent. In some embodiments suitable solvents comprise aromatic hydrocarbons. The method may further comprise additional steps including, but not limited to, washing the electrode surface to remove excess silanizing agent, excess solvent, or both; and drying the electrode, for example in a stream of inert gas.

Any electrically conductive material may be used as the counter electrode. In particular embodiments any suitable known counter electrode permitting reduction of the oxidant in the electrolyte may be used as the counter electrode. Illustrative examples of suitable counter electrodes comprise a platinum electrode, a platinum-comprising electrode, a platinum-coated conductor electrode, a rhodium electrode, a ruthenium electrode and a carbon electrode.

Any suitable known redox electrolytes may be used for the purpose of the present invention. Illustrative redox pairs comprise I⁻/I₃⁻, Br⁻/Br₃⁻ and quinone/hydroquinone pairs. Such a redox electrolyte system may be prepared by any known method. For example, the I⁻/I₃⁻-type redox electrolyte may be prepared by mixing pairs such as an inorganic iodide and iodine, or an organic iodide and iodine, wherein illustrative inorganic iodides comprise sodium iodide and lithium iodide, and illustrative organic iodides comprise imidazolium iodides; 1-methyl-3-propylimidazolium iodide; tetraalkyl ammonium iodides, and tetra-n-propylammonium iodide. As a solvent for the electrolyte, there may be used an electrochemically inert solvent capable of dissolving the electrolyte in a large amount, such as, but not limited to, acetonitrile, propylene carbonate, or ethylene carbonate. The electrolyte may be liquid or solid. The solid electrolyte may be obtained by dispersing the electrolyte in a polymeric material or by employing a gel in which the electrolyte fills the pores in a polymeric matrix. Other hole conducting solid phases such as polycrystalline copper salts including, but not limited to, CuI or CuSCN, or amorphous organic glasses comprised of aromatic amines or conducting polymers may be used for the electrolyte. Suitable electrolyte mixtures may also comprise such compounds as imidazolium trifluoromethanesulfonimides, 1-methyl-3-propyl-imidazolium trifluoromethanesulfonimide, N-methylbenzimidazole; alkylpyridines, and 4-t-butylpyridine.

Without further elaboration, it is believed that one skilled in the art can, using the description herein, utilize the present invention to its fullest extent. The following examples are included to provide additional guidance to those skilled in the art in practicing the claimed invention. The examples provided are merely representative of the work that contributes to the teaching of the present application. Accordingly, these examples are not intended to limit the invention, as defined in the appended claims, in any manner.

A dye sensitized solar cell (DSSC) plate assembly comprised a sandwich of layers of materials encapsulated by two glass plates, one plate comprising a titania electrode and the other plate comprising a platinum electrode. When sealed together, the DSSC plate assembly enclosed 6 separate and individual solar cells. The fabrication procedure employed six steps and included: (i) tin oxide glass preparation and Ag bus printing for both the titania and platinum electrodes; (ii) titania deposition, firing, and dye absorption for the titania electrode; (iii) passivation and rinsing of the titania electrode; (iv) platinum deposition and firing of the platinum electrode; (v) assembly, filling of electrolyte, and final sealing of the assembly; and (vi) testing of the assembly.

In step (i) fluoride-doped tin oxide (FTO) coated glass plates, type Tec 8, were obtained from Hartford Glass Company. Each glass plate was 7.6 centimeters (cm)×10.2 cm in size, and had a surface resistivity Ohm rating of 8 Ohms/square. Grooves were cut into some glass plates to serve as the TiO₂ or titania electrodes in order to break the conductive coating across the plate and to provide separate compartments for each of the 6 solar cells (5 millimeters (mm)×50 mm each). In addition holes to be used for electrolyte filling were drilled into the plates to serve as the platinum electrodes. A silver bus was then applied onto both types of plates using a screen-printing deposition method and silver paste (type #7713 from Dupont). The plates were then fired at 525° C. for 30 minutes.

In step (ii) a titanium dioxide paste from ECN (Energy Research Centre of the Netherlands, Petten, The Netherlands) was applied to appropriate plates using a screen-printing technique. Each of the 6 cells was defined in this step to comprise a 5 mm×50 mm, approximately 10 micron thick, strip of nano-crystalline titania. Plates with titania electrode were then placed in an ethanol atmosphere to facilitate relaxation of the paste, followed by firing at 450° C. for 30 minutes in an oxygen atmosphere. After firing, plates with titania electrode were submerged into a dye solution and allowed to soak at least overnight. Dye solutions were made from dyes obtained from Solaronrix (Aubonne, Switzerland) and included either 0.3 millimolar (mM) type Ruthenium 520-DN (cis-bis(isothiocyanato)(2,2′-bipyridyl4,4′-dicarboxylato)(4,4′-n-nonyl-2,2′-bipyridyl)ruthenium(II)) dye dissolved in a 1:1 mixture of dry acetonitrile and dry t-butanol; or 0.3 mM type Ruthenium 535 (cis-bis(isothiocyanato)bis(2,2′-bipyridyl-4,4′-dicarboxylato)-ruthenium(II)) dye in dry ethanol. The plates were then removed from the dye solution, rinsed with dry solvent, and dried in a stream of nitrogen.

In step (iii) the plates comprising dyed titania electrodes were soaked in a solution of silanizing agent in a closed box in a dry environment, for example in 10 vol. % silanizing agent in dry toluene. The plates were allowed to soak for 4-72 hours, typically overnight. The plates were then soaked two times for 1 hour each time in dry toluene, followed by a final soak of one hour in dry acetonitrile. After the final wash, the plates were dried under a stream of dry nitrogen.

In step (iv) approximately 1 ml of a coating solution of hexachloroplatinic acid (5 mM in isopropanol) was uniformly dispensed from a glass syringe onto each plate (3-4 drops per cell) for the platinum electrode using a doctor-blading technique. The plates was allowed to dry, and then fired at 385° C. in a nitrogen atmosphere for 15 minutes.

After preparation of both titania and platinum electrodes, the plates were ready for assembly. The two electrodes and electrolyte are typically accommodated in a case or encapsulated with a resin, in such a state that the dye-sensitized oxide semiconductor electrode is capable of being irradiated with a light. In a particular embodiment a pre-cut gasket, 40 microns in thickness and composed of PRIMACOR 5980I (an ethylene-acrylic acid copolymer with melt index of 300 grams per 10 minutes and an acrylic acid level of 20.5%), was aligned on top of the titania electrode plate. Six approximately rectangular slots were cut in this gasket. Each slot was larger than and was placed over the previously printed 5 mm×50 mm titania strips. The platinum electrode plate was then placed on the top of the gasket and titania electrode plate. The sandwiched layers were then inserted into a hot press that had been pre-heated to 90° C., and the assembly was pressed for 45 seconds. After allowing the assembly to cool, electrolytes were introduced into the six individual spaces defined by the slots in the gasket, each space including one printed titania strip, by insertion of a syringe into the holes located in the platinum electrode plate. A vacuum line attached to the opposite hole of the platinum electrode plate aided in electrolyte filling. When electrolyte filling was completed, the syringe and vacuum were removed from the holes, and the holes were sealed using a hot press and an additional piece of PRIMACOR material and glass strip. All these steps were accomplished in a nitrogen glove box in a dry atmosphere, and the plates were removed only after the final sealing.

Step (vi) involved the testing of the assembled device. The device was placed into a testing apparatus that provided separate contacts to each cell. Each cell was then illuminated and tested under 1 sun conditions (AM1.5, 100 milliwatts per square centimeter light intensity) using a ThermoOriel sun simulator and source-measure unit from Keithley Instruments.

### EXAMPLES 1-6 AND COMPARATIVE EXAMPLES 1-6

Plate assemblies were prepared comprising Ruthenium 535 type dye and various ionic liquid electrolytes. In examples 1-6 the titania electrode was silanized using n-octyltrimethoxysilane (10 volume % in dry toluene). In comparative examples 1-6 the titania electrode was not silanized. Table 1 shows the molarity (M) of the individual components in the mixed electrolyte compositions used in the different plate assemblies in both examples (Ex.) 1-6 and in the corresponding comparative examples (C.Ex.) 1-6. The electrolyte components were (i) 1-methyl-3-propyl-imidazolium iodide (imidazolium iodide); (ii) iodine (I₂); and (iii) 4-t-butylpyridine. Certain electrolytes were in an ionic liquid salt solvent of 1-methyl-3-propyl-imidazolium trifluoromethanesulfonimide.

TABLE 1

| Ex. or C. Ex. | imidazolium iodide (M) | I₂ (M) | t-butylpyridine (M) |
|---|---|---|---|
| 1* | 1.93 | 0.16 | 0.5 |
| 2* | 1.93 | 0.50 | 0.5 |
| 3 | 4.78 | 0.16 | 0.5 |
| 4 | 4.78 | 0.50 | 0.5 |
| 5* | 2.88 | 0.27 | 0.5 |
| 6* | 3.83 | 0.39 | 0.5 |

*molarity in 1-methyl-3-propyl-imidazolium trifluoromethanesulfonimide solvent

Table 2 shows physical properties of the illuminated plate assemblies of both examples and comparative examples. The properties measured included open circuit voltage (Voc) in millivolts, closed circuit current density (J-short circuit or Jsc) in milliamperes per square centimeter, fill factor (FF), and power efficiency (Eff). The data show that open circuit voltage (Voc) and closed circuit current density (Jsc) are improved by silanization with every electrolyte, leading to improved power efficiency in all cases.

TABLE 2

| Ex. or C. Ex. | Voc | Jsc | FF | Eff |
|---|---|---|---|---|
| C. Ex. 1 | 471.3 | 8.3 | 0.37 | 1.44% |
| Ex. 1 | 530.9 | 9.5 | 0.33 | 1.66% |
| C. Ex. 2 | 472.6 | 6.0 | 0.46 | 1.31% |
| Ex. 2 | 511.4 | 7.2 | 0.44 | 1.60% |
| C. Ex. 3 | 521.4 | 8.8 | 0.30 | 1.36% |
| Ex. 3 | 560.2 | 9.5 | 0.28 | 1.48% |
| C. Ex. 4 | 510.7 | 6.9 | 0.46 | 1.61% |
| Ex. 4 | 561.9 | 7.8 | 0.48 | 2.09% |
| C. Ex. 5 | 527.1 | 7.6 | 0.45 | 1.78% |
| Ex. 5 | 548.3 | 8.4 | 0.44 | 2.04% |
| C. Ex. 6 | 510.3 | 7.1 | 0.45 | 1.61% |
| Ex. 6 | 543.4 | 8.5 | 0.45 | 2.10% |

### EXAMPLES 7-9 AND COMPARATIVE EXAMPLES 7-9

Plate assemblies were prepared comprising Ruthenium 535 type dye and various ionic liquid electrolytes. In examples 7-9 the titania electrode was silanized using n-octyltrimethoxysilane (10 volume % in dry toluene) under different conditions. In comparative examples 7-9 the titania electrode was not silanized. Table 3 shows the molarity (M) of the individual components in the mixed electrolyte compositions used in the different plate assemblies in both examples 7-9 and in the corresponding comparative examples 7-9. The electrolyte components were (i) tetra-n-propylammonium iodide (n-Pr₄NI); (ii) lithium iodide; (iii) 1-methyl-3-propyl-imidazolium iodide (imidazolium iodide); (iv) iodine (I₂); and (v) 4-t-butylpyridine. Certain electrolytes were in acetonitrile solvent and others were in an ionic liquid salt solvent of 1-methyl-3-propyl-imidazolium trifluoromethanesulfonimide.

TABLE 3

| Ex. or | n-Pr₄NI | | imidazolium | | t-butylpyridine |
|---|---|---|---|---|---|
| C. Ex. | (M) | LiI (M) | iodide (M) | I₂ (M) | (M) |
| 7* | 0.5 | 0.1 | — | 0.05 | 0.5 |
| 8** | — | — | 3.06 | 0.275 | 0.225 |
| 9** | — | — | 3.06 | 0.275 | 0.45 |

*molarity in acetonitrile solvent
**molarity in 1-methyl-3-propyl-imidazolium trifluoromethanesulfonimide solvent

Table 4 shows physical properties of the illuminated plate assemblies of both examples and comparative examples. The data show that open circuit voltage (Voc) and closed circuit current density (Jsc) are improved by silanization with every electrolyte, leading to improved power efficiency in all cases.

TABLE 4

| | | | | |
|---|---|---|---|---|
| Ex. or C. Ex. | Voc | Jsc | FF | Eff |

Unsilanized cells

| | | | | |
|---|---|---|---|---|
| C. Ex. 7 | 668 | 10.86 | 0.61 | 4.42% |
| C. Ex. 8 | 547 | 8.04 | 0.49 | 2.16% |
| C. Ex. 9 | 519 | 8.05 | 0.46 | 1.91% |

Unsilanized cells soaked in toluene overnight

| | | | | |
|---|---|---|---|---|
| C. Ex. 7 | 680 | 11.57 | 0.57 | 4.50% |
| C. Ex. 8 | 550 | 7.94 | 0.48 | 2.08% |
| C. Ex. 9 | 532 | 8.16 | 0.47 | 2.04% |

Cells silanized for 4 hours

| | | | | |
|---|---|---|---|---|
| Ex. 7 | 711 | 11.97 | 0.63 | 5.36% |
| Ex. 8 | 574 | 8.91 | 0.52 | 2.83% |
| Ex. 9 | 589 | 9.20 | 0.47 | 2.57% |

Cells silanized overnight

| | | | | |
|---|---|---|---|---|
| Ex. 7 | 697 | 12.12 | 0.63 | 5.32% |
| Ex. 8 | 610 | 8.92 | 0.49 | 2.65% |
| Ex. 9 | 572 | 8.74 | 0.46 | 2.34% |

### EXAMPLES 10-21

Plate assemblies were prepared comprising Ruthenium 535 type dye and various ionic liquid electrolytes. In examples 10-21 the titania electrode was silanized using different silanizing agents (all 0.39 M in dry toluene). Table 5 shows the molarity (M) of the individual components in the mixed electrolyte compositions used in the different plate assemblies in examples 10-21. The electrolyte components were (i) tetra-n-propylammonium iodide (n-Pr₄NI); (ii) lithium iodide; (iii) 1-methyl-3-propyl-imidazolium iodide (imidazolium iodide); (iv) iodine (I₂); and (v) 4-t-butylpyridine. Certain electrolytes were in acetonitrile solvent and others were in an ionic liquid salt solvent of 1-methyl-3-propyl-imidazolium trifluoromethanesulfonimide.

TABLE 5

| Electrolyte | n-Pr₄NI | | imidazolium | | t-butylpyridine |
|---|---|---|---|---|---|
| type | (M) | LiI (M) | iodide (M) | I₂ (M) | (M) |
| A* | 0.5 | 0.1 | — | 0.05 | 0.5 |
| B** | — | — | 3.06 | 0.275 | 0.225 |

*molarity in acetonitrile solvent
**molarity in 1-methyl-3-propyl-imidazolium trifluoromethanesulfonimide solvent

The silanizing agents employed were n-octyltrimethoxysilane (C8); hexyltrimethoxysilane (C6), 2,4,4-trimethylpentyltrimethoxysilane (iC8), octadecyltrimethoxysilane (C18), hexadecyltrimethoxysilane (C16) and dodecyltrimethoxysilane (C12). Table 6 shows physical properties of the illuminated plate assemblies of both examples and comparative examples. The data are listed in order of decreasing efficiency value for each electrolyte type. In comparison to unsilanized comparative example 7 which also comprised the electrolyte type A, the data for examples 10-15 show that open circuit voltage (Voc) and closed circuit current density (Jsc) are improved by silanization, leading to improved power efficiency in all cases except the C18 and iC8 silanizing agents. In comparison to unsilanized comparative example 8 which also comprised the electrolyte type B, the data for examples 16-21 show that open circuit voltage (Voc) and closed circuit current density (Jsc) are improved by silanization, leading to improved power efficiency in all cases except the C18 and iC8 silanizing agents.

TABLE 6

| | | | | | | |
|---|---|---|---|---|---|---|
| | Silanizing | Electrolyte | | | | |
| Example | agent | type | Voc | Jsc | FF | Eff |

| | | | | | | |
|---|---|---|---|---|---|---|
| 10 | C8 | A | 709 | 12.4 | 0.63 | 5.5% |
| 11 | C6 | A | 702 | 12.2 | 0.59 | 5.0% |
| 12 | C12 | A | 707 | 12.0 | 0.58 | 5.0% |
| 13 | C16 | A | 707 | 11.5 | 0.54 | 4.4% |
| 14 | C18 | A | 624 | 11.6 | 0.56 | 4.0% |
| 15 | iC8 | A | 660 | 10.5 | 0.57 | 4.0% |
| 16 | C8 | B | 594 | 9.1 | 0.46 | 2.5% |
| 17 | C16 | B | 606 | 8.9 | 0.45 | 2.4% |
| 18 | C6 | B | 593 | 8.8 | 0.44 | 2.3% |
| 19 | C12 | B | 587 | 8.7 | 0.44 | 2.2% |
| 20 | C18 | B | 530 | 7.2 | 0.37 | 1.4% |
| 21 | iC8 | B | 550 | 6.4 | 0.40 | 1.4% |

### EXAMPLES 22-23 AND COMPARATIVE EXAMPLES 10-11

Plate assemblies were prepared comprising Ruthenium 520-DN type dye and various ionic liquid electrolytes. In examples 22-23 the titania electrode was silanized using n-octyltrimethoxysilane (10 volume % in dry toluene). In comparative examples 10-11 the titania electrode was not silanized. Table 7 shows the molarity (M) of the individual components in the mixed electrolyte compositions used in the different plate assemblies in examples 22-23 and in the corresponding comparative examples 10-11. The electrolyte components were (i) iodine (I₂); (ii) N-methylbenzimidazole (NMB); and (iii) 1-methyl-3-propyl-imidazolium iodide (imidazolium iodide). One electrolyte mixture was in an ionic liquid salt solvent of 1-methyl-3-propyl-imidazolium trifluoromethanesulfonimide.

TABLE 7

| | | | imidazolium |
|---|---|---|---|
| Ex./C. Ex. | I₂ (M) | NMB (M) | iodide (M) |
| 22/10 | 0.5 | 0.45 | 5.61 |
| 23*/11* | 0.275 | 0.45 | 3 |

*molarity in 1-methyl-3-propyl-imidazolium trifluoromethanesulfonimide solvent

Table 8 shows physical properties of the illuminated plate assemblies of both examples and comparative examples. The data show that open circuit voltage (Voc) and closed circuit current density (Jsc) are improved by silanization with each electrolyte, leading to improved power efficiency in both cases.

TABLE 8

| Ex. or C. Ex. | Voc | Jsc | FF | Eff |
|---|---|---|---|---|
| C. Ex. 10 | 583.2 | 8.63 | 0.47 | 2.38% |
| Ex. 22 | 617.3 | 10.30 | 0.47 | 3.01% |
| C. Ex. 11 | 559.8 | 9.36 | 0.45 | 2.33% |
| Ex. 23 | 592.3 | 10.88 | 0.45 | 2.89% |

### EXAMPLES 24-27 AND COMPARATIVE EXAMPLES 12-13

Plate assemblies were prepared comprising Ruthenium 520-DN type dye and various ionic liquid electrolytes. In examples 24-27 the titania electrode was silanized using different silanizing agents (all 10 volume % in dry toluene). In comparative examples 12-13 the titania electrode was not silanized. Table 9 shows the molarity (M) of the individual components in the mixed electrolyte compositions used in the different plate assemblies in examples 24-27 and in comparative examples 12-13. The electrolyte components were (i) tetra-n-propylammonium iodide (n-Pr₄NI); (ii) lithium iodide; (iii) 1-methyl-3-propyl-imidazolium iodide (imidazolium iodide); (iv) iodine (I₂); (v) 4-t-butylpyridine; and (vi) N-methylbenzimidazole (NMB). One electrolyte mixture was in acetonitrile solvent.

TABLE 9

| Electrolyte | n-Pr₄NI | LiI | imidazolium | NMB | I₂ | t-butylpyridine |
|---|---|---|---|---|---|---|
| type | (M) | (M) | iodide (M) | (M) | (M) | (M) |
| A* | 0.5 | 0.1 | — | — | 0.05 | 0.5 |
| B | — | 0.1 | 5.61 | 0.45 | 0.5 | — |

*molarity in acetonitrile solvent

The silanizing agents employed were n-octyltrimethoxysilane (C8), and 1,8-bis(triethoxysilyl)octane (BTESO). Table 10 shows physical properties of the illuminated plate assemblies of both examples and comparative examples. In comparison to unsilanized comparative example 12 which also comprised the electrolyte type B, the data for examples 24-25 show that open circuit voltage (Voc) and closed circuit current density (Jsc) are improved by silanization, leading to improved power efficiency in all cases. In comparison to unsilanized comparative example 13 which also comprised the electrolyte type A, the data for examples 26-27 show that open circuit voltage (Voc) and closed circuit current density (Jsc) are improved by silanization, leading to improved power efficiency in examples 27 and 29.

TABLE 10

| Ex. or | | Silanizing | | | | |
|---|---|---|---|---|---|---|
| C. Ex. | Electrolyte | agent | Voc | Jsc | FF | Eff |
| 24 | B | BTESO | 633 | 9.62 | 0.43 | 2.62 |
| 25 | B | C8 | 642 | 9.85 | 0.45 | 2.85 |
| C. Ex. 12 | B | none | 595 | 8.48 | 0.38 | 1.93 |
| 26 | A | BTESO | 671 | 13.82 | 0.63 | 5.87 |
| 27 | A | C8 | 675 | 13.73 | 0.58 | 5.39 |
| C. Ex. 13 | A | none | 635 | 12.82 | 0.63 | 5.17 |

### EXAMPLES 28-31

Plate assemblies were prepared comprising Ruthenium 520-DN type dye and various ionic liquid electrolytes. Plates were submerged into the dye solution and allowed to soak for 24 hours. In examples 28-31 the titania electrode was silanized using different silanizing agents (all 0.39 M in dry toluene). Table 11 shows the molarity (M) of the individual components in the mixed electrolyte compositions used in the different plate assemblies in examples 28-31. The electrolyte components were (i) lithium iodide; (ii) 1-methyl-3-propyl-imidazolium iodide (imidazolium iodide); (iii) N-methylbenzimidazole (NMB); and (iv) iodine (I₂).

TABLE 11

| Electrolyte | | imidazolium | | |
|---|---|---|---|---|
| type | LiI (M) | iodide (M) | NMB (M) | I₂ (M) |
| A | — | 5.61 | 0.45 | 0.5 |
| B | 0.1 | 5.61 | 0.45 | 0.5 |

The silanizing agents employed were n-octyltrimethoxysilane (C8); and 2-(perfluorohexylethyl)trimethoxysilane (C₆F₁₃CH₂CH₂Si(OMe)₃; referred to as “C6F13”). Table 12 shows physical properties of the illuminated plate assemblies of the examples. In comparison to unsilanized comparative example 10 above, which also comprised the electrolyte type A, the data for examples 28-29 show that open circuit voltage (Voc) and closed circuit current density (Jsc) are improved by silanization, leading to improved power efficiency. In comparison to unsilanized comparative sample 12 above, which also comprised the electrolyte type B, the data for examples 30-31 show that open circuit voltage (Voc) and closed circuit current density (Jsc) are improved by silanization, leading to improved power efficiency.

TABLE 12

| | | Silanizing | | | | |
|---|---|---|---|---|---|---|
| Ex. | Electrolyte | agent | Voc | Jsc | FF | Eff |
| 28 | A | C8 | 628.2 | 9.37 | 0.46 | 2.70% |
| 29 | A | C6F13 | 630.3 | 9.66 | 0.44 | 2.68% |
| 30 | B | C8 | 685.7 | 9.58 | 0.51 | 3.36% |
| 31 | B | C6F13 | 684.9 | 9.81 | 0.50 | 3.36% |

### EXAMPLES 32-35 AND COMPARATIVE EXAMPLES 14-17

Plate assemblies were prepared comprising Ruthenium 520-DN type dye and various ionic liquid electrolytes. Certain plate assemblies also comprised an alumina-coated titania electrode. To produce the alumina-coated titania electrode the freshly fired titania electrodes were submerged in 0.1 M aluminum tri-sec-butoxide in dry isopropanol for 20 minutes at 60° C., rinsed twice in dry isopropanol, submerged in water at 80° C., and finally fired at 450° C. for 20 minutes (referred to as treatment 1). Both alumina-coated and uncoated titania electrodes were dyed in the usual manner by submerging in dye solution overnight. Some of these titania electrodes (both alumina-coated and uncoated) were subsequently silanized by treating the electrode with n-octyltrimethoxysilane (C8) (10 vol. % in dry toluene overnight), followed by 2 soaks in dry toluene for 1 hour each, then 1 soak of 1 hour in dry acetonitrile and drying in a stream of nitrogen (referred to as treatment 2). Table 13 shows the molarity (M) of the individual components in the mixed electrolyte compositions used in the different plate assemblies in examples 32-35. The electrolyte components were (i) 1-methyl-3-propyl-imidazolium iodide (imidazolium iodide); (ii) N-methylbenzimidazole (NMB); and (iii) iodine (I₂). One electrolyte mixture was in an ionic liquid salt solvent of 1-methyl-3-propyl-imidazolium trifluoromethanesulfonimide.

TABLE 13

| Electrolyte | imidazolium | | |
|---|---|---|---|
| type | iodide (M) | NMB (M) | I₂ (M) |
| A | 5.61 | 0.45 | 0.5 |
| B* | 3.0 | 0.45 | 0.275 |

*molarity in 1-methyl-3-propyl-imidazolium trifluoromethanesulfonimide solvent

Table 14 shows physical properties of the illuminated plate assemblies of both the examples and comparative examples. The data show that open circuit voltage (Voc) and closed circuit current density (Jsc) are improved by silanization (treatment 2) with each electrolyte, leading to improved power efficiency in both cases. Although coating the titania electrode with alumina (treatment 1 alone) did not improve efficiency in the case of either electrolyte, nevertheless both treating with alumina and silanizing the electrode (treatment 1+2) resulted in physical properties nearly equivalent to the examples of silanized titania electrode without alumina coating.

TABLE 14

| Ex. or | | | | | | |
|---|---|---|---|---|---|---|
| C. Ex. | Electrolyte | Treatment | Voc | Jsc | FF | Eff |
| C. Ex. 14 | A | none | 583.2 | 8.63 | 0.47 | 2.38% |
| 32 | A | 2 | 617.3 | 10.30 | 0.47 | 3.01% |
| C. Ex. 15 | A | 1 | 575.8 | 8.28 | 0.45 | 2.12% |
| 33 | A | 1 + 2 | 616.5 | 9.71 | 0.49 | 2.92% |
| C. Ex. 16 | B | none | 559.8 | 9.36 | 0.45 | 2.33% |
| 34 | B | 2 | 592.3 | 10.88 | 0.45 | 2.89% |
| C. Ex. 17 | B | 1 | 553.8 | 8.87 | 0.45 | 2.20% |
| 35 | B | 1 + 2 | 603.5 | 10.20 | 0.43 | 2.63% |

While the invention has been illustrated and described in typical embodiments, it is not intend to be limited to the details shown, since various modifications and substitutions can be made without departing in any way from the spirit of the present invention. As such, further modifications and equivalents of the invention herein disclosed may occur to persons skilled in the art using no more than routine experimentation, and all such modifications and equivalents are believed to be within the spirit and scope of the invention as defined by the following claims. All Patents and published articles cited herein are incorporated herein by reference.

1. A dye-sensitized oxide semiconductor electrode comprising an electrically conductive substrate, an oxide semiconductor film provided on a surface of said electrically conductive substrate, and a sensitizing dye adsorbed on said film, wherein the oxide semiconductor film has been further treated with at least one silanizing agent comprising the partial structure R¹—Si—OR², wherein R¹ and R² are each independently alkyl groups, or R¹ is an alkyl group and R² is hydrogen or aryl.

2. The electrode of claim 1, wherein the electrically conductive substrate comprises a glass plate on which an electrically conductive layer comprising either In₂O₃ or SnO₂ is laminated, or an electrically conductive metal foil or plate, or an electrically conducting ceramic, or a ceramic coated with an electrical conductor, or an electrically conductive polymer.

3. The electrode of claim 1, wherein the oxide semiconductor comprises an oxide of a metal selected from the group consisting of Ti, Nb, Zn, Sn, Zr, Y, La, Ta, W, Hf, Sr, In, V, Cr, Mo; a perovskite oxide selected from the group consisting of SrTiO₃ and CaTiO₃; and mixtures thereof.

4. The electrode of claim 3, wherein the oxide semiconductor comprises titania.

5. The electrode of claim 3, wherein the oxide semiconductor comprises a metal oxide coating.

6. The electrode of claim 5, wherein the coating comprises alumina, silica, zirconia, or niobium oxide.

7. The electrode of claim 5, wherein the oxide semiconductor comprises titania coated with alumina.

8. The electrode of claim 1, wherein the dye comprises a coumarin, a cyanine, a merocyanine, a polymethine, a perylene, a squaraine, a porphyrin, or a phthalocyanine, optionally further comprising a metal.

9. The electrode of claim 1, wherein the dye comprises at least one ruthenium or osmium complex.

10. The electrode of claim 1, wherein the silanizing agent is selected from the group consisting of alkylsilanes of the formula R¹ₙSi(OR²)₄₋ₙ; bis(trisilyl)alkanes of the formula R¹(Si(OR²)₃)₂; tris(trisilyl)alkanes of the formula R¹(Si(OR²)₃)₃; tetrakis(trisilyl)alkanes of the formula R¹(Si(OR²)₃)₄, wherein the parameter n has a value of 1-3 inclusive and R¹ and R² are each independently alkyl groups, or R¹ is an alkyl group and R² is hydrogen or aryl;
functionalized silylalkanes with charged groups of the formula (R²O)₃Si(CH₂)ₘPO₃⁻X⁺, wherein R² is hydrogen, alkyl or aryl, the counterion X comprises tetraalkylammonium, and the parameter m has a value in the range of 2-16 inclusive; or those of the formula (R²O)₃Si(CH₂)ₘNR³₃⁺Y⁻, wherein R² is hydrogen, alkyl or aryl, R³ is an alkyl group, the counterion Y comprises iodide, and the parameter m has a value in the range of 2-16 inclusive; and silylated polyethylenes of the formula (I)
—[CH₂CH₂]ₚ—[CH₂CH(SiR¹ₙ(OR²)₃₋ₙ)]ₓ— (I)
wherein R¹ and R² are each independently hydrogen, alkyl or aryl, the parameter n has a value of 1-3 inclusive, and the parameters p and x each independently have a value in a range of about 4-100.

11. The electrode of claim 10, wherein the silanizing agent is selected from the group consisting of n-hexyltrimethoxysilane, n-octyltrimethoxysilane, isooctyltrimethoxysilane, 2,4,4-trimethylpentyltrimethoxysilane, octadecyltrimethoxysilane, hexadecyltrimethoxysilane, dodecyltrimethoxysilane, 1,8-bis(triethoxysilyl)octane, 1,10-bis(trimethoxysilyl)decane, 1,12-bis(trimethoxysilyl)dodecane, 1,14-bis(trimethoxysilyl)tetradecane, 1,16-bis(trimethoxysilyl)hexadecane and 2-(perfluorohexylethyl)trimethoxysilane.

12. A dye-sensitized oxide semiconductor electrode comprising (i) an electrically conductive substrate comprising a glass plate on which an electrically conductive layer comprising either In₂O₃ or SnO₂ is laminated, or an electrically conductive metal foil or plate, or an electrically conducting ceramic, or a ceramic coated with an electrical conductor, or an electrically conductive polymer; (ii) an oxide semiconductor film comprising either titania or alumina-coated titania provided on a surface of said electrically conductive substrate, and (iii) a sensitizing dye comprising a ruthenium complex adsorbed on said film, wherein the oxide semiconductor film has been further treated with at least one silanizing agent selected from the group consisting of n-hexyltrimethoxysilane, n-octyltrimethoxysilane, isooctyltrimethoxysilane, 2,4,4-trimethylpentyltrimethoxysilane, octadecyltrimethoxysilane, hexadecyltrimethoxysilane, dodecyltrimethoxysilane, 1,8-bis(triethoxysilyl)octane, 1,10-bis(trimethoxysilyl)decane, 1,12-bis(trimethoxysilyl)dodecane, 1,14-bis(trimethoxysilyl)tetradecane, 1,16-bis(trimethoxysilyl)hexadecane and 2-(perfluorohexylethyl)trimethoxysilane.

13. A solar cell comprising a dye-sensitized oxide semiconductor electrode according to claim 1, a counter electrode, and a redox electrolyte contacting with said dye-sensitized oxide semiconductor electrode and said counter electrode.

14. A solar cell comprising a dye-sensitized oxide semiconductor electrode according to claim 12, a counter electrode, and a redox electrolyte contacting with said dye-sensitized oxide semiconductor electrode and said counter electrode.

15. A method for improving the efficiency of a solar cell comprising an electrically conductive substrate, an oxide semiconductor film provided on a surface of said electrically conductive body, and a sensitizing dye adsorbed on said film which comprises the step of passivating the oxide semiconductor with at least one silanizing agent comprising the partial structure R¹—Si—OR², wherein R¹ and R² are each independently alkyl groups, or R¹ is an alkyl group and R² is hydrogen or aryl.

16. The method of claim 15, wherein the electrically conductive substrate comprises a glass plate on which an electrically conductive layer comprising either In₂O₃ or SnO₂ is laminated, or an electrically conductive metal foil or plate, or an electrically conducting ceramic, or a ceramic coated with an electrical conductor, or an electrically conductive polymer.

17. The method of claim 15, wherein the oxide semiconductor comprises an oxide of a metal selected from the group consisting of Ti, Nb, Zn, Sn, Zr, Y, La, Ta, W, Hf, Sr, In, V, Cr, Mo; a perovskite oxide selected from the group consisting of SrTiO₃ and CaTiO₃; and mixtures thereof.

18. The method of claim 17, wherein the oxide semiconductor comprises titania.

19. The method of claim 17, wherein the oxide semiconductor comprises a metal oxide coating.

20. The method of claim 19, wherein the coating comprises alumina, silica, zirconia, or niobium oxide.

21. The method of claim 19, wherein the oxide semiconductor comprises titania coated with alumina.

22. The method of claim 15, wherein the dye comprises a coumarin, a cyanine, a merocyanine, a polymethine, a perylene, a squaraine, a porphyrin, or a phthalocyanine, optionally further comprising a metal.

23. The method of claim 15, wherein the dye comprises at least one ruthenium or osmium complex.

24. The method of claim 15, wherein the silanizing agent is selected from the group consisting of alkylsilanes of the formula R¹ₙSi(OR²)₄₋ₙ; bis(trisilyl)alkanes of the formula R¹Si(OR²)₃)₂; tris(trisilyl)alkanes of the formula R¹(Si(OR²)₃)₃; tetrakis(trisilyl)alkanes of the formula R¹(Si(OR²)₃)₄, wherein the parameter n has a value of 1-3 inclusive and R¹ and R² are each independently alkyl groups, or R¹ is an alkyl group and R² is hydrogen or aryl;
functionalized silylalkanes with charged groups of the formula (R²O)₃Si(CH₂)ₘPO₃⁻X⁺, wherein R² is hydrogen, alkyl or aryl, the counterion X comprises tetraalkylammonium, and the parameter m has a value in the range of 2-16 inclusive; or those of the formula (R²O)₃Si(CH₂)ₘNR³₃⁺Y⁻, wherein R² is hydrogen, alkyl or aryl, R³ is an alkyl group, the counterion Y comprises iodide, and the parameter m has a value in the range of 2-16 inclusive; and silylated polyethylenes of the formula (I)
—[CH₂CH₂]ₚ—[CH₂CH(SiR¹ₙ(OR²)₃₋ₙ)]ₓ— (I)
wherein R¹ and R² are each independently hydrogen, alkyl or aryl, the parameter n has a value of 1-3 inclusive, and the parameters p and x each independently have a value in a range of about 4-100.

25. The method of claim 24, wherein the silanizing agent is selected from the group consisting of n-hexyltrimethoxysilane, n-octyltrimethoxysilane, isooctyltrimethoxysilane, 2,4,4-trimethylpentyltrimethoxysilane, octadecyltrimethoxysilane, hexadecyltrimethoxysilane, dodecyltrimethoxysilane, 1,8-bis(triethoxysilyl)octane, 1,10-bis(trimethoxysilyl)decane, 1,12-bis(trimethoxysilyl)dodecane, 1,14-bis(trimethoxysilyl)tetradecane, 1,16-bis(trimethoxysilyl)hexadecane and 2-(perfluorohexylethyl)trimethoxysilane.
